(19) United States
(12) Patent Application Publication
(10) Pub. No.: US 2025/0298712 A1
(43) Pub. Date: Sep. 25, 2025

(54) PROGRAMMABLE PROCESSOR FOR MEMORY TELEMETRY

(71) Applicant: Micron Technology, Inc., Boise, ID (US)

(72) Inventor: David Andrew Roberts, Wellesley, MA (US)

(21) Appl. No.: 19/071,422

(22) Filed: Mar. 5, 2025

Related U.S. Application Data
(60) Provisional application No. 63/568,549, filed on Mar. 22, 2024.

(51) Int. Cl. G06F 11/30; G06F 9/30

(52) U.S. Cl. CPC G06F 11/3037; G06F 9/3001; G06F 11/3072

(57) ABSTRACT

A memory sub-system includes a processor to store a reference value in a register, wherein the reference value represents a total available bandwidth of a memory sub-system. The processor is further configured to measure a current bandwidth usage within the memory sub-system, and determine a percentage of available bandwidth of the memory sub-system based on the current bandwidth usage and the reference value in the register. The processor is further configured to collect a set of data values representative of a latency statistic in the memory sub-system, and determine a moving average of the set of data values based on a predefined number of recent data values to smooth fluctuations in the latency statistic. The processor is further configured to store the moving average in a designated register in the memory sub-system.

### REFERENCE TO RELATED APPLICATION

This application claims the priority benefit of U.S. Provisional Patent Application No. 63/568,549, filed Mar. 22, 2024, the entirety of which is incorporated herein by reference.

### TECHNICAL FIELD

Embodiments of the disclosure relate generally to memory sub-systems, and more specifically, relate to a programmable processor for memory telemetry in a memory sub-system.

### BACKGROUND

A memory sub-system can include one or more memory components that store data. The memory components can be, for example, non-volatile memory components and volatile memory components. In general, a host system can utilize a memory sub-system to store data at the memory components and to retrieve data from the memory components.

### BRIEF DESCRIPTION OF THE DRAWINGS

The present disclosure will be understood more fully from the detailed description given below and from the accompanying drawings of various embodiments of the disclosure.

FIG. 1 illustrates an example computing environment that includes a memory sub-system in accordance with some embodiments of the present disclosure.

FIG. 2 illustrates an example computing environment that includes a memory sub-system in accordance with some embodiments of the present disclosure.

FIG. 3 is a flow diagram of an example method for performing memory telemetry, in accordance with some embodiments of the present disclosure.

FIG. 4 is a flow diagram of an example method for performing memory telemetry, in accordance with some embodiments of the present disclosure.

FIG. 5 is a flow diagram of an example method for performing memory telemetry, in accordance with some embodiments of the present disclosure.

FIG. 6 is a block diagram of an example computer system in which embodiments of the present disclosure may operate.

### DETAILED DESCRIPTION

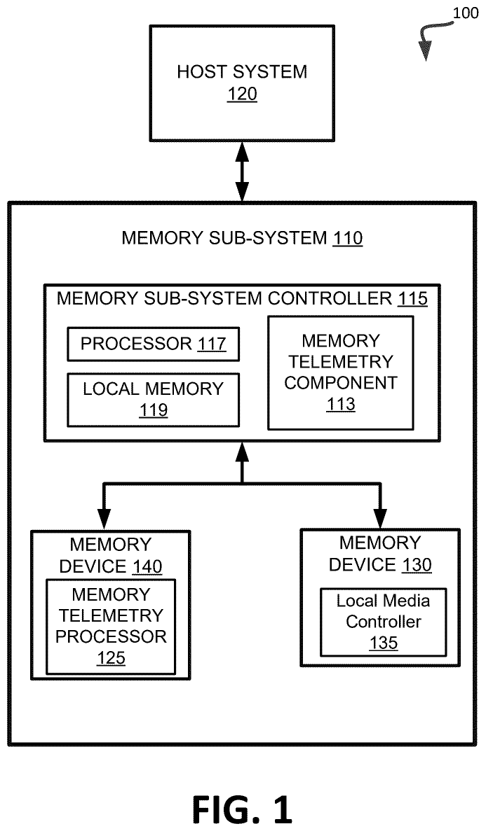

Aspects of the present disclosure are directed to memory telemetry in a memory sub-system. A memory sub-system can be a storage device, a memory module, or a hybrid of a storage device and memory module. Examples of storage devices and memory modules are described below in conjunction with FIG. 1. In general, a host system can utilize a memory sub-system that includes one or more memory components, such as memory devices that store data. The host system can provide data to be stored at the memory sub-system and can request data to be retrieved from the memory sub-system.

A memory device can be a non-volatile memory device. A non-volatile memory device is a package of one or more dies. Each die can consist of one or more planes. For some types of non-volatile memory devices (e.g., negative-and (NAND) devices), each plane consists of a set of physical blocks. Each block consists of a set of pages. Each page consists of a set of memory cells, which store bits of data. For some memory devices, such as NAND devices, blocks are the smallest area that can be erased and pages within the blocks cannot be erased individually. For such devices, erase operations are performed one block at a time.

The host system can send access requests (e.g., write command, read command) to the memory sub-system, such as to store data on a memory device at the memory sub-system and to read data from the memory device on the memory sub-system. The data to be read or written, as specified by a host request, is hereinafter referred to as “host data.” A host request can include logical address information (e.g., logical block address (LBA), namespace) for the host data, which is the location the host system associates with the host data. The logical address information (e.g., LBA, namespace) can be part of metadata for the host data. Metadata can also include error handling data (e.g., ECC codeword, parity code), data version (e.g., used to distinguish age of data written), valid bitmap (which LBAs or logical transfer units contain valid data), etc.

“System data” hereinafter refers to data that is created and/or maintained by the memory sub-system for performing operations in response to host requests and for media management. Examples of system data include, and are not limited to, system tables (e.g., logical-to-physical address mapping table), data from logging, scratch pad data, etc.

Memory telemetry (MT) refers to the collection and analysis of data related to the performance and usage of a memory device. MT may be used to optimize memory usage and diagnose memory-related issues to ensure system performance and reliability. MT data collected inside a memory module often needs to be post-processed before being stored, temporarily or permanently, for use in host system decision making or for further data processing (e.g., data migration, prefetching, caching, compression, transformation, etc.). This can be a memory-intensive and compute-intensive process that can consume significant bandwidth between a host processor and a memory module. For some memory devices (e.g., a double data rate (DDR) dynamic random-access memory (DRAM) or a compute express link (CXL) memory device), requests arriving from a host processor can be spaced apart by as little as a clock cycle, or less than a nanosecond. In some instances, processing and summarizing information about request and response packets needs to be performed in real time without slowing down the memory device or adding latency. General-purpose processors are highly programmable but they have multi-cycle instructions and unpredictable delays due to memory stalls.

Aspects of the present disclosure address the above and other deficiencies by having a memory sub-system that processes high-bandwidth telemetry data in-place without the need for transmitting the data to a host system or storing internally. Reducing the movement of data within the system while getting the same result results in increased bandwidth, decreased latency, and reduced energy usage. Some embodiments relate to a processor for processing of memory telemetry in real time. Example use cases include generating prefetch predictions from page address streams for memory tiering, sorting heat maps for memory tiering, data compression, monitoring for security purposes, anomaly detection and pattern matching (e.g., using regular expressions).

Advantages of the present disclosure include, but are not limited to, enabling post-processing of telemetry data at the memory sub-system level so that it can take some workload off a host processor. Additionally, the additional processor does not cause a performance bottleneck, which a general-purpose processor can cause.

FIG. 1 illustrates an example computing environment 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and a non-volatile dual in-line memory module (NVDIMM).

The computing environment 100 can include a host system 120 that is coupled to one or more memory sub-systems 110. In some embodiments, the host system 120 is coupled to different types of memory sub-system 110. FIG. 1 illustrates one example of a host system 120 coupled to one memory sub-system 110. The host system 120 uses the memory sub-system 110, for example, to write data to the memory sub-system 110 and read data from the memory sub-system 110. As used herein, “operatively coupled to” generally refers to a connection between components, which can be an indirect communicative connection or direct communicative connection (e.g., without intervening components), whether wired or wireless, including connections such as electrical, optical, magnetic, etc.

The host system 120 can be a computing device such as a desktop computer, laptop computer, network server, mobile device, embedded computer (e.g., one included in a vehicle, industrial equipment, or a networked commercial device), or such computing device that includes a memory and a processing device. An example of a host system 120 is a surveillance system or a recording device (e.g., camera) of a surveillance system, high speed recording devices, action/sport cameras, etc. The host system 120 can be coupled to the memory sub-system 110 via a physical host interface. Examples of a physical host interface include, but are not limited to, a compute express link (CXL), a serial advanced technology attachment (SATA) interface, a peripheral component interconnect express (PCIe) interface, universal serial bus (USB) interface, Fibre Channel, Serial Attached SCSI (SAS), etc. The physical host interface can be used to transmit data between the host system 120 and the memory sub-system 110. The host system 120 can further utilize an NVM Express (NVMe) interface to access the memory components (e.g., memory devices 130) when the memory sub-system 110 is coupled with the host system 120 by the PCIe interface. The physical host interface can provide an interface for passing control, address, data, and other signals between the memory sub-system 110 and the host system 120.

The memory devices can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

An example of non-volatile memory devices (e.g., memory device 130, 140) includes a negative-and (NAND) type flash memory. Each of the memory devices 130 can include one or more arrays of memory cells such as single level cells (SLCs), multi-level cells (MLCs), triple level cells (TLCs), or quad-level cells (QLCs). In some embodiments, a particular memory component can include an SLC portion, and an MLC portion, a TLC portion, or a QLC portion of memory cells. Each of the memory cells can store one or more bits of data used by the host system 120. Furthermore, the memory cells of the memory devices 130 can be grouped as memory pages or memory blocks that can refer to a unit of the memory component used to store data.

Although non-volatile memory components such as NAND type flash memory are described, the memory device 130 can be based on any other type of non-volatile memory, such as read-only memory (ROM), phase change memory (PCM), magneto random access memory (MRAM), negative-or (NOR) flash memory, electrically erasable programmable read-only memory (EEPROM), and a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased.

The memory sub-system controller 115 can communicate with the memory devices 130, 140 to perform operations such as reading data, writing data, refreshing data, or erasing data at the memory devices 130, 140 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 may not include a memory sub-system controller 115, and may instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130, 140. The memory sub-system controller 115 can be responsible for other operations such as wear leveling operations, garbage collection operations, error detection and error-correcting code (ECC) operations, encryption operations, caching operations, and address translations between a logical block address and a physical block address that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130, 140 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130, 140.

In some embodiments, the memory devices 130 include local media controllers 135 that operate in conjunction with memory sub-system controller 115 to execute operations on one or more memory cells of the memory devices 130. In some embodiments, the memory devices 130 are managed memory devices, which is a raw memory device combined with a local controller (e.g., the local media controller 135) for memory management within the same memory device package.

The memory sub-system 110 includes a memory telemetry component 113 that can be used to perform memory telemetry functions with the memory sub-system 110. In some embodiments, the controller 115 includes at least a portion of the memory telemetry component 113. For example, the controller 115 can include a processor 117 (processing device) configured to execute instructions stored in local memory 119 for performing the operations described herein. In some embodiments, the memory telemetry component 113 is part of the host system 120, an application, or an operating system.

In some embodiments, the memory telemetry component 113 can generate prefetch predictions from page address streams for memory tiering, sort heat maps for memory tiering, perform data compression, monitor for security purposes, anomaly detection and pattern matching (e.g., using regular expressions). Further details with regards to the operations of the memory telemetry component 113 are described below.

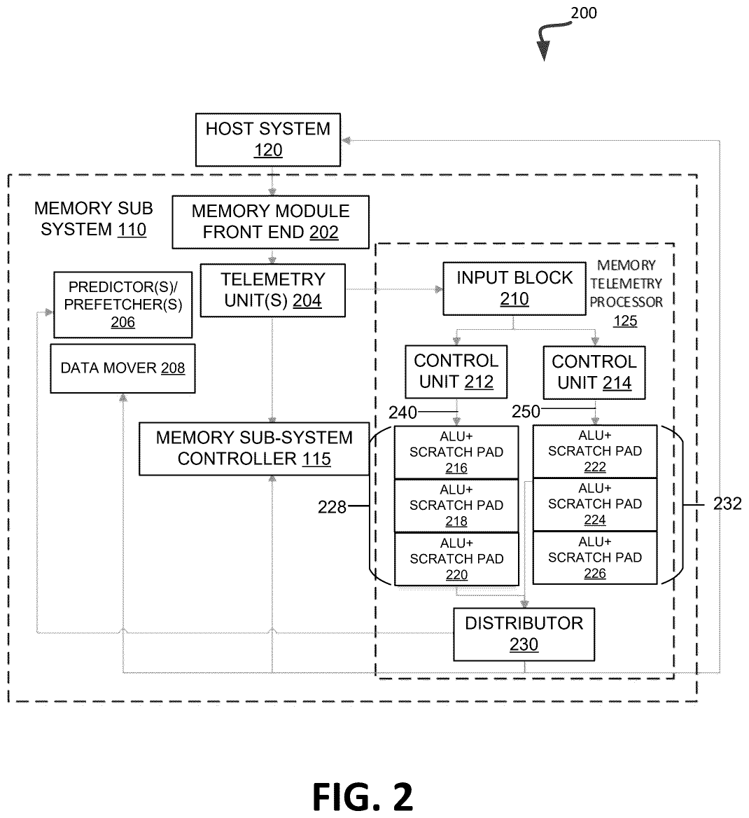

FIG. 2 illustrates an example computing environment 200 that includes a memory sub-system 110 in accordance with some embodiments of the present disclosure. The memory sub-system 110 may include a memory telemetry processor 125 that may be separate from and in addition to the memory sub-system controller 115. The memory telemetry processor 125 may be configured to perform one or more telemetry functions as described below. The memory telemetry processor 125 may be implemented by a special purpose processing device that includes a control unit 212 that may be coupled to an array 228 of one or more arithmetic logic units (ALUs) 216-220 connected by a pipeline 240. The memory telemetry processor 125 may further include a control unit 214 that may be coupled to an array 232 of one or more arithmetic logic units (ALUs) 222-226 connected by a pipeline 250. Each of the control units 212, 214 may use a respective binary decoder to convert input instructions into timing and control signals that direct the operation of other units like memory, ALUs 216-226, and input/output (I/O) devices. An input block 210 may be used to direct data to either pipeline 240 or pipeline 250, or both, based on one or more criteria. ALUs 216-226 may perform arithmetic and logic operations. They can execute a variety of operations such as addition, subtraction, multiplication, and division, as well as logical operations like AND, OR, NOT, and XOR. Each of the ALUs 216-226 may be associated with one or more scratchpads (e.g., high-speed RAMs) for temporary storage during the execution of one or more operations. The combination of ALUs and scratchpads may help in optimizing the performance of the memory telemetry processor 125, especially for tasks that require rapid data retrieval and computation. A host interface (e.g., CXL, PCIe) may connect the host system 120 to the memory telemetry processor 125 and the memory sub-system controller 115. A memory module front end 202 may receive a request to access memory, which may include a specific memory address. The memory module front end 202 may interpret this address to determine which memory cells should be accessed. The memory module front end 202 may translate the memory sub-system controller's 115 and host commands into actions that the memory telemetry processor 125 can understand and execute. The memory module front end 202 may manage the electrical signals that represent data and control instructions moving to and from the memory sub-system 110. It may ensure that these signals are correctly timed, formatted, and synchronized with the system clock. The memory module front end 202 may also interpret and control the timing of execution of various memory operations such as reading data from memory, writing data to memory, and refreshing the data stored in memory. The memory module front end 202 may manage the data bus or host interface, which is the channel through which data is sent to and received from a memory device. This may involve handling the timing and control signals to ensure that data is transferred correctly and efficiently. The memory module front end 202 may also handle operations such as error correction to ensure data integrity. The memory module front end 202 may also perform tasks like leveling, buffering, or re-timing signals to maintain signal integrity.

A distributor unit 230 may be coupled to the one or more ALUs 216-220 and the ALUs 222-226 to receive data from either or both arrays 228, 232, and send an output of the memory telemetry processor 125 to either the host system 120, an internal predictor or data prefetcher 206, a data mover 208, an interconnect fabric manager (not shown), a memory buffer, or a direct memory access (DMA) engine in the memory sub-system, or an external memory device. The ALUs 216-226 may be interconnected through a configurable interconnect, such as a mesh network-on-chip including one or more routers (not shown). The fabric manager may control the mesh network external to the memory module (e.g., in a multi-module CXL system). The fabric manager may also set permissions on portions of memory modules and allow access to a host system. The fabric manager and/or the host system may download a program and internal telemetry processor interconnect configuration, which may specify the processes the fabric manager may perform and what type of statistics the fabric manager may generate.

The data predictor or data prefetcher 206 may proactively fetch data and instructions from the distributor unit 230 before they are actually needed for execution. The data predictor or data prefetcher 206 may reduce memory access latency and improve the overall performance of the memory telemetry processor 125.

In some embodiments, the data predictor and prefetcher 206 may anticipate the data and instructions that the memory telemetry processor 125 likely needs in the future. It may use one or more algorithms to predict these needs based on current and past operations of the memory telemetry processor 125. In some embodiments, the data predictor or data prefetcher 206 may prefetch data from one or more CXL device memories and save it to the host DRAM or cache to improve performance of the host system. The operation of the data prefetcher 206 may be controlled by the statistics generated by the memory telemetry processor 125, which may relate to requests of the host system based on address patterns. The host system may send a message to the memory telemetry processor 125 embedded in the memory sub-system 110. The message can include a source address or source addresses to be prefetched from a memory device. The memory telemetry processor 125 can receive the message and initiate transfers (e.g., direct memory access (DMA) transfers) of the prefetched data from the memory device.

A data mover 208 may handle the transfer of data blocks from one location to another within the memory sub-system 110. By handling data transfers, the data mover 208 can offload some tasks from the host system 120. This may allow the host system 120 to focus more on processing tasks rather than spending cycles on moving data. In some embodiments, the data mover 208 may include a direct memory access (DMA) engine to reduce latency in data transfers.

In some embodiments, the control unit 212 may receive data packets from the host system 120, and the control unit 212 may select one or more packets from the data packets based on one or more selection criteria. In some embodiments, the data packets may be selected based on a type of data packet, for example, command packets, address packets, write data packets, read data packets, status packets, erase packets, spare area packets, and metadata packets. In some embodiments, the data packets may be selected based on the type of metric measured by the telemetry units 204. The type of metrics measured by the telemetry units 204 include but are not limited to temperature readings, voltage and power consumption, error rates, wear and endurance metrics, usage statistics, bandwidth and throughput metrics, latency measurements, event logs, and environmental factors. In some embodiments, the selection criteria may be a combination of the type of data packet and the type of metric measured by the telemetry units, and the selection criteria may be set by the host system 120 and/or the memory sub-system controller 115 or fabric manager. The telemetry units 204 may monitor and collect various operational parameters and performance metrics. This data may be used by the host system 120 to understand the state and health of the memory device, as well as for optimizing the performance and reliability of the memory device. For example, telemetry units 204 may generate temperature readings of one or more memory devices. In some embodiments, the telemetry units 204 can track the voltage levels and power consumption of the memory devices to ensure that the memory device operates within specified power requirements. In some embodiments, the telemetry units 204 can report on the rate of errors detected and corrected, which is an indicator of the health and reliability of the memory device. In some embodiments, the telemetry units 204 can monitor and report on the wear level of memory cells, which may assist in predicting the lifespan of the memory device and in implementing wear-leveling algorithms. In some embodiments, the telemetry units 204 may generate data on how much memory is being used, access patterns, and the distribution of read and write operations, which may be used by the host system 120 for performance optimization and capacity planning. The telemetry units 204 may also report event logs, for example, logs of events such as errors, interruptions, or maintenance actions.

The control unit 212 may then perform one or more operations on the one or more data packets, and send the one or more data packets to the one or more ALUs 216-220 for further processing. For example, the control unit 212 may interpret and execute commands received from the memory sub-system controller 115, including but not limited to read, write, erase, or modify data in the memory device. For operations that require accessing specific memory locations (like read and write operations), the control unit decodes the address information in the data packets to identify the correct location in the memory. In some embodiments, the control unit 212 may manage buffers where data packets are temporarily stored during read and write operations. In some embodiments, the control unit 212 may check data packets for errors and apply correction code, if necessary. In some embodiments, the control unit 212 may manage the timing of operations, ensuring that data packets are processed in the correct sequence and at the right speed, in accordance with the specifications and the system timing requirements. The control unit 212 may also handle the formatting of data packets, including encoding data for storage and decoding it for retrieval. Upon receiving a read or write command, the control unit 212 may initiate the corresponding operation, managing the flow of data packets to or from the memory cells. The control unit 212 may also generate status reports about the success or failure of operations, the current state of the memory (e.g., ready, busy, or error states). In some implementations, the control unit 212 may be involved in wear leveling, and distributing write and erase cycles across the memory cells to extend the memory device's lifespan.

Similarly, the control unit 214 may receive data packets from the host system 120, and the control unit 214 may select one or more data packets based on one or more selection criteria. In some embodiments, the data packets may be selected based on a type of data packet, for example, command packets, address packets, write data packets, read data packets, status packets, erase packets, spare area packets, and metadata packets. In some embodiments, the data packets may be selected based on the type of metric measured by the telemetry units 204. The type of metrics measured by the telemetry units 204 include but are not limited to temperature readings, voltage and power consumption, error rates, wear and endurance metrics, usage statistics, bandwidth and throughput metrics, latency measurements, event logs, and environmental factors. In some embodiments, the selection criteria may be a combination of the type of data packet and the type of metric measured by the telemetry units, and the selection criteria may be set by the host system 120 and/or the memory sub-system controller 115. The control unit 214 may then perform one or more operations described above, and send the one or more data packets to the one or more ALUs 222-226 for further processing. In some embodiments, the selection may be based on a type of data packet or a type of metric measured by the telemetry units 204. In some embodiments, control unit 212 may populate a local memory of the one or more ALUs 216-220 with one or more scaling factors or one or more temporary variables. Similarly, control unit 214 may populate a local memory of the one or more ALUs 222-226 with one or more scaling factors or one or more temporary variables. The ALUs 216-220 and/or the ALUs 222-226 may include at least one of a coarse-grained reconfigurable architecture (CGRA) or a field programmable gate array (FPGA) type architecture where different blocks (e.g., ALUs) are connected via a configurable interconnect such as a mesh network on-chip.

Control units 212, 214 may include general-purpose processors that can handle commands from the host system 120 and orchestrate configuration of the pipelined ALUs 216-226 and the ALU interconnect network. For example, control units 212, 214 can load the instruction memories, scratchpads, and memory files of the ALUs 216-226. One or more inputs from the telemetry units 204 may be received by control units 212, 214 as they arrive or are routed to the specific control unit depending on incoming request packet type, or type of telemetry unit generating the input data. The control units 212, 214 may include an instruction memory that may perform one or more operations on the data before it is passed on to the ALUs in the pipeline. As a result, the number of ALUs and operations can be scaled depending on the amount of post-processing required, while keeping up with the rapid flow of input data and not causing back-pressure that may stall the memory. Each ALU 216-226 may include some local memory or a register file for fast access to parameters such as scaling factors (e.g., for data normalization), and temporary variables. The control units 212, 214 or the host system 120 or fabric manager can populate these local memories.

In some embodiments, memory telemetry processor 125 may generate a “heat map” identifying data blocks that are accessed more frequently using one or more colors and identifiers and identifying data blocks that are accessed less frequently using another color(s). In one implementation, the memory telemetry processor 125 may determine a frequency with which a data block in a memory device is accessed by the host system 120 over a period of time. The memory telemetry processor 125 may determine that the frequency with which the data block is accessed exceeds a threshold value, and send some or all of the data from the data block to another memory device. The other memory device may be selected based on having a lower latency, lower utilization, or higher bandwidth than the memory device from the data being moved. This operation may be referred to as “memory tiering” where data blocks that are important or have higher access rates may be moved to memory devices or “tiers” that have a lower latency, lower utilization, or higher bandwidth than the memory device from the data being moved. In some embodiments, the access rates may be determined based on a count of memory read and write requests received from the host system 120. In some embodiments, the memory sub-system 110 or memory module may include a double data rate (DDR) dynamic random-access memory (DRAM) or a compute express link (CXL) memory device.

In some embodiments, input block 210 may receive a sequence of request packets from the host system 120 and response packets from one or more memory devices. The memory telemetry processor may select, monitor, and process the packet fields. In some embodiments, the packet fields may include one or more page addresses, a type of operation, or a timestamp. One or more dedicated telemetry units 204 may filter or transform the incoming requests before reaching the memory telemetry processor 125.

In some embodiments, the memory telemetry processor 125 may gather data about various aspects of memory usage. This can include information about memory capacity, utilization, access patterns, read/write speeds, latency, error rates, and temperature. The memory telemetry processor 125 may also track page faults, cache hits and misses, and other metrics that may be relevant to the memory sub-system 110. By analyzing this data, the memory telemetry processor 125 may monitor the performance of the memory subsystem 110. It can identify bottlenecks or inefficiencies, such as areas where memory access is slower than expected, or where contention for memory resources is impacting system performance. In some embodiments, the memory telemetry processor 125 may be used for predictive maintenance. For example, by monitoring memory health indicators such as error rates and wear levels (e.g., in SSDs), the memory telemetry processor 125 may be able to predict and prevent failures before they occur. In some embodiments, the memory telemetry processor 125 may be able to optimize system configuration for better performance. For example, it may adjust memory allocation, tuning garbage collection in software, or reconfiguring the way applications use the memory.

In some embodiments, the memory telemetry processor 125 may be used for troubleshooting memory-related issues. For example, in a server environment, sudden spikes in memory usage or unusual access patterns can indicate problems such as memory leaks in software or malicious activities like a denial-of-service attack. The memory telemetry processor 125 may be able to predict the access patterns as described below, and thus avoid any problems like memory leaks. In some embodiments, the memory telemetry data is analyzed in real-time, allowing immediate response to memory performance issues. The output of the memory telemetry processor 125 from the distributor unit 230 can either be consumed by the host system 120, a fabric manager, or internal predictors, prefetchers and control processors inside the module. Alternatively, or in addition they can be streamed into an in-module memory buffer, an external memory device, or back to the host system 120. Other statistical operations that may be performed by the memory telemetry processor 125 include, but are not limited to, thresholding, averaging, principal component analysis (PCA), generating a histogram (e.g., by determining frequency of a variable or factor that impacts performance of the memory sub-system), regression analysis, etc. Regression analysis may involve, for example, identifying one or more variables or factors that impact performance of the memory sub-system.

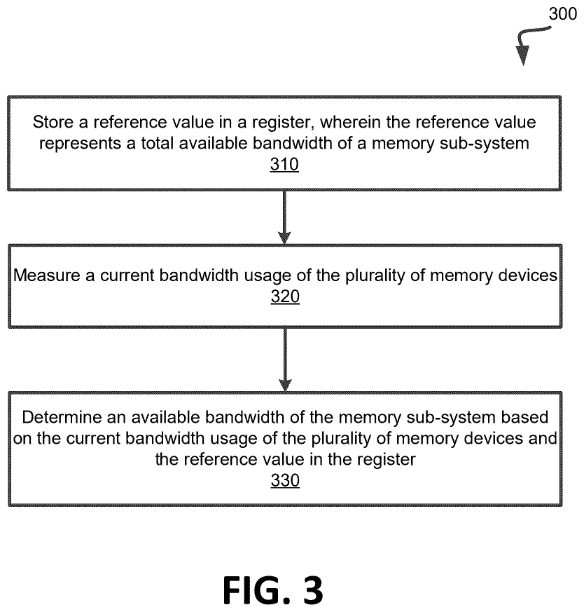

FIG. 3 is a flow diagram of an example method 300 for performing memory telemetry in a memory sub-system (e.g., memory sub-system 110), in accordance with some embodiments of the present disclosure. The method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 300 is performed by the memory telemetry component 113 of FIG. 1 and/or the memory telemetry processor 125 of FIG. 2. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

Method 300 may be executed to determine a percentage bandwidth of a memory sub-system (e.g., memory sub-system 110). At operation 310, the processing device may store a reference value in a register. The reference value may represent, for example, a total available bandwidth of the memory sub-system. At operation 320, the processing device may measure a current bandwidth usage of the memory devices within the memory sub-system. In one example, the processing device may measure a speed by which a read or write operation is performed on the memory sub-system. In one example, measuring the current bandwidth usage may include capturing data transfer rates of one or more memory devices in the memory sub-system over a predetermined time interval. At operation 330, the processing device determines an available bandwidth of the memory sub-system based on the current bandwidth usage of the memory devices and the reference value in the register. In one example, the processing device may divide the current bandwidth usage by the reference value in the register to determine the percentage of available bandwidth of the memory sub-system.

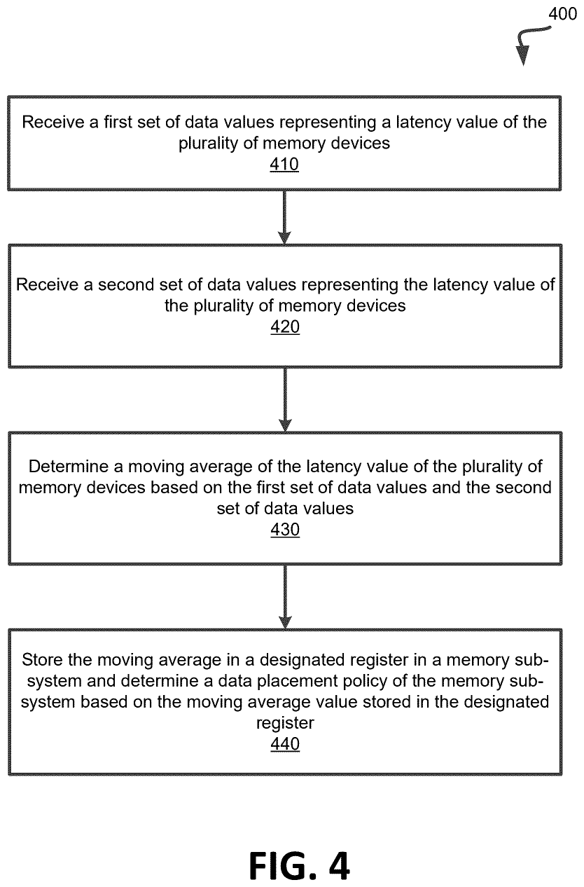

FIG. 4 is a flow diagram of an example method 400 for performing memory telemetry in a memory sub-system (e.g., memory sub-system 110), in accordance with some embodiments of the present disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by the memory telemetry component 113 of FIG. 1 and/or the memory telemetry processor 125 of FIG. 2. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

Method 400 may be executed to smooth a latency statistic of the memory sub-system. At operation 410, the processing device may collect a set of data values representative of a latency statistic in the memory sub-system. The latency statistic is a measurement that quantifies the delay or time it takes for data to travel from a source to a destination in a memory module. It may represent the time interval between the initiation of a request or an action and the moment when the desired response or outcome is received or completed. In one example, the processing device may measure the time it takes to access data from the storage medium. It may include components like seek time and/or data transfer time. In one example, the processing device may receive a set of data values representing a latency value of one or more memory devices. At operation 420, the processing device may receive another set of data values representing a latency value of the one or more memory devices. At block 430, the processing device may determine a moving average of the latency value of the memory devices based on the two or more sets of data values or a predefined number of recent data values to smooth fluctuations in the latency statistic. In one implementation, collecting the set of data values may include measuring latency over a series of discrete time intervals. In a further operation, the processing device may adjust the predefined number of recent data values based on a performance criteria of the memory sub-system. For example, a lower latency may lead to faster response time of the memory sub-system. At operation 440, the processing device may store the moving average in a designated register in the memory sub-system. The processing device may further determine a data placement policy of the memory sub-system based on the moving average value stored in the designated register. For example, the processing device may identify data blocks that are accessed more frequently than others. In one implementation, the processing device may determine a frequency with which a data block in a memory device is accessed by a host system over a period of time. The processing device may determine that the frequency with which the data block is accessed is over a threshold value and send some or all of the data from the data block to an external memory device. The external memory device may be selected based on having a lower latency, lower utilization, or higher bandwidth than the memory device from the data being moved. In some embodiments, the access rates may be determined based on a count of memory read and write requests received from the host system.

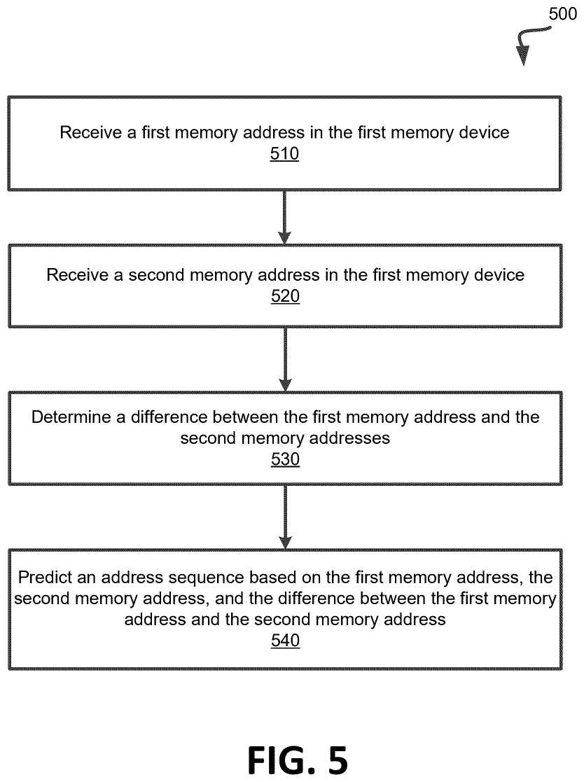

FIG. 5 is a flow diagram of an example method 500 for performing memory telemetry in a memory sub-system (e.g., memory sub-system 110), in accordance with some embodiments of the present disclosure. The method 500 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 is performed by the memory telemetry component 113 of FIG. 1 and/or the memory telemetry processor 125 of FIG. 2. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

Method 500 may be executed to reduce memory latency and allow the memory telemetry processor to execute host instructions more quickly. At operation 510, the processing device may receive a first memory address in a memory device of a memory sub-system. The memory address may include, for example, a page address, block address, or a wordline address. At operation 520, the processing device may receive a second memory address in a memory device of a memory sub-system. The memory address may include, for example, a page address, block address, or a wordline address. At operation 530, the processing device may determine a difference between the current memory address and a prior memory address received from the host system, either to perform a read operation or a write operation at that address. At operation 540, the processing device may predict an address sequence based on the current memory address, prior memory address, and the difference between the current memory address and the prior memory address. For example, if the first address is that of page 1, and the second address is that of page 4 in a block, then the processing device may determine that the size of access is 3 pages (i.e., 4-1) and therefore the next page that would be accessed in the block is page 7. At operation 540, the processing device may use the predicted address sequence for pre-fetching data from the host system. For example, the processing device may keep/load data in page 7 ready to perform a read or write operation. This may reduce memory latency and allow the memory telemetry processor to execute host instructions more quickly.

In some embodiments, the processing device may improve memory access latency by predicting and fetching data that is likely to be accessed in the near future before it is actually requested. One objective is to reduce the time it takes to retrieve data when a request is made, thereby improving overall system performance. In some embodiments, the processing device may use adaptive read-ahead algorithms to predict which data blocks will be accessed next and load them into memory.

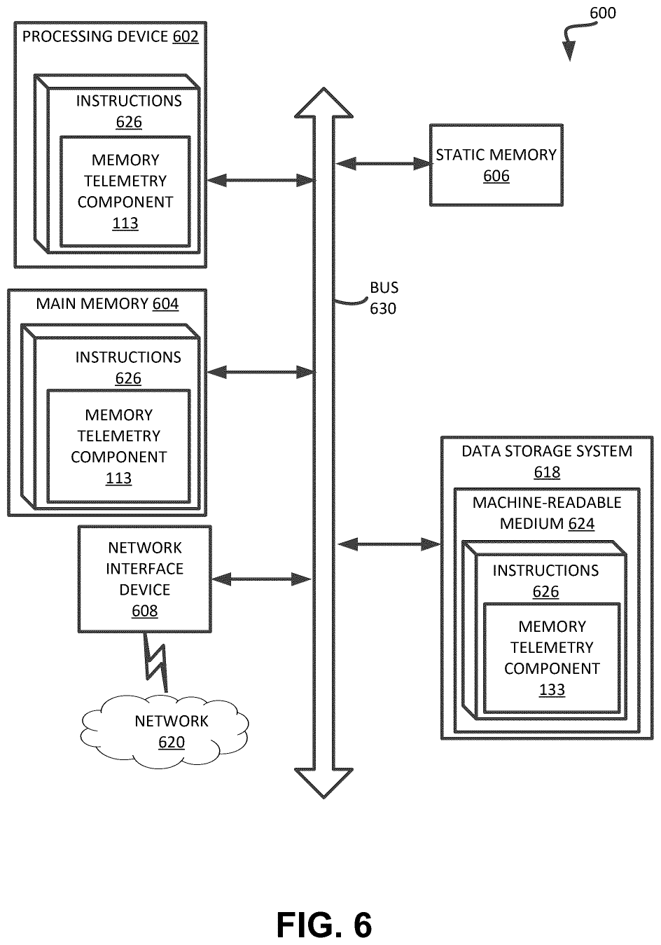

FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the memory telemetry component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random-access memory (DRAM) such as synchronous DRAM (SDRAM) or Rambus DRAM (RDRAM), etc.), a static memory 606 (e.g., flash memory, static random access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein. The computer system 600 can further include a network interface device 608 to communicate over the network 620.

The data storage system 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIG. 1.

In one embodiment, the instructions 626 include instructions to implement functionality corresponding to a memory telemetry component (e.g., the memory telemetry component 113 of FIG. 1). While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A memory sub-system comprising:
a plurality of memory devices; and
a processor operatively coupled with the plurality of memory devices, the processor comprising:
a first control unit operatively coupled to one or more first arithmetic logic units (ALUs) connected by a first pipeline;
a second control unit operatively coupled to one or more second arithmetic logic units (ALUs) connected by second pipeline; and
a distributor unit operatively coupled to the one or more first ALUs and the one or more second ALUs, wherein the processor is to perform operations, comprising:
determining a frequency with which a first data block in a first memory device is accessed by a host system over a first period of time; and
sending, responsive to determining that the frequency satisfies a first threshold criterion, data from the first data block to a second memory device.

2. The memory sub-system of claim 1, wherein a plurality of ALUs comprising at least one of the first ALUs or at least one of the second ALUs are interconnected through a configurable interconnect.

3. The memory sub-system of claim 2, wherein the configurable interconnect comprises a mesh network-on-chip comprising one or more routers.

4. The memory sub-system of claim 1, wherein the first control unit is to perform operations, comprising:
receiving a plurality of data packets from a host system;
selecting one or more packets from the plurality of data packets;
performing one or more operations on the one or more data packets; and
sending the one or more data packets to at least one of the one or more first ALUs.

5. The memory sub-system of claim 4, wherein the selecting is based on a type of data packet or a type of metric measured by a telemetry unit generating the data packet.

6. The memory sub-system of claim 1, wherein the one or more first ALUs and the one or more second ALUs comprise at least one of a coarse-grained reconfigurable architecture (CGRA) or a field programmable gate array (FPGA).

7. The memory sub-system of claim 1, wherein the first memory device and the second memory device comprise at least one of: a double data rate (DDR) dynamic random-access memory (DRAM) or a compute express link (CXL) memory device.

8. The memory sub-system of claim 1, wherein the processor is to perform further operations comprising:
storing a reference value in a register, wherein the reference value represents a maximum bandwidth of the memory sub-system;
measuring a current bandwidth usage of the plurality of memory devices; and
determining an available bandwidth of the memory sub-system based on the current bandwidth usage of the plurality of memory devices and the reference value in the register.

9. The memory sub-system of claim 8, wherein measuring the current bandwidth usage of the plurality of memory devices further comprises capturing respective data transfer rates of the plurality of memory devices over a second period of time.

10. The memory sub-system of claim 1, wherein the processor is to perform further operations comprising:
receiving a first set of data values representing a latency value of the plurality of memory devices;
receiving a second set of data values representing the latency value of the plurality of memory devices;
determining a moving average of the latency value of the plurality of memory devices based on the first set of data values and the second set of data values;
storing the moving average in a designated register in a memory sub-system; and
determining a data placement policy of the memory sub-system based on the moving average value stored in the designated register.

11. The memory sub-system of claim 10, wherein receiving the first set of data values further comprises measuring the latency of the plurality of memory devices over a third period of time.

12. The memory sub-system of claim 1, wherein the processor is to perform further operations comprising:
adjusting a predefined number of the second set of data values based on a performance criteria of the memory sub-system.

13. The memory sub-system of claim 1, wherein the processor is to perform further operations comprising:
receiving a first memory address in the first memory device;
receiving a second memory address in the first memory device;
determining a difference between the first memory address and the second memory addresses;
predicting an address sequence based on the first memory address, the second memory address, and the difference between the first memory address and the second memory address; and
using the predicted address sequence for pre-fetching data from a host system.

14. The memory sub-system of claim 1, wherein the second memory device has a lower latency, lower utilization, or higher bandwidth than the first memory device.

15. A method, comprising:
determining, by a processing device, a frequency with which a first data block in a first memory device is accessed by a host system over a first period of time, wherein the frequency reflects a count of read and write requests received from the host system during the first period of time; and
sending, responsive to determining that the frequency satisfies a first threshold criterion, data from the first data block to a second memory device, wherein the second memory device has a lower latency, lower utilization, or higher bandwidth than the first memory device.

16. The method of claim 15, further comprising:
storing, by the processing device, a reference value in a register, wherein the reference value represents a maximum bandwidth of a memory sub-system;
measuring a current bandwidth usage of the plurality of memory devices; and
determining an available bandwidth of the memory sub-system based on the current bandwidth usage of the plurality of memory devices and the reference value in the register.

17. The method of claim 15, further comprising:
receiving a first set of data values representing of a latency value of the plurality of memory devices;
receiving a second set of data values representing of the latency value of the plurality of memory devices;
determining a moving average of the latency value of the plurality of memory devices based on the first set of data values and the second set of data values;
storing the moving average in a designated register in a memory sub-system; and
determining a data placement policy based on the moving average value stored in the designated register.

18. The method of claim 15, further comprising:
receiving a first memory address in the first memory device;
receiving a second memory address in the first memory device;
determining a difference between the first memory address and the second memory addresses;
predicting an address sequence based on the first memory address, the second memory address, and the difference between the first memory address and the second memory address; and
using the predicted address sequence for pre-fetching data from a host system.

19. A non-transitory computer-readable storage medium comprising instructions that, when executed by a processing device, cause the processing device to perform operations, comprising:
storing a reference value in a register, wherein the reference value represents a total available bandwidth of a memory sub-system;
measuring a current bandwidth usage within the memory sub-system; and
determining a percentage of available bandwidth of the memory sub-system based on the current bandwidth usage and the reference value in the register.

20. The non-transitory computer-readable storage medium of claim 19, wherein the processing device is further to perform operations, comprising:
collecting a set of data values representative of a latency statistic in the memory sub-system;
determining a moving average of the set of data values based on a predefined number of recent data values to smooth fluctuations in the latency statistic;
storing the moving average in a designated register in the memory sub-system; and
determining a data placement policy in the memory sub-system based on the moving average value stored in the designated register.
